(19) United States
(12) Patent Application Publication
(10) Pub. No.: US 2023/0116381 A1
(43) Pub. Date: Apr. 13, 2023

(54) SYSTEM AND METHOD FOR HIGH THROUGHPUT DEFECT INSPECTION IN A CHARGED PARTICLE SYSTEM

(71) Applicant: ASML Netherlands B.V., Veldhoven (NL)

(72) Inventors: Long MA, San Jose, CA (US); Zhonghua DONG, San Jose, CA (US); Te-Yu CHEN, San Jose, CA (US)

(73) Assignee: ASML Netherlands B.V., Veldhoven (NL)

(21) Appl. No.: 17/911,121

(22) PCT Filed: Mar. 9, 2021
(86) PCT No.: PCT/EP2021/055954

§ 371 Date: Sep. 12, 2022

Related U.S. Application Data
(60) Provisional application No. 62/988,817, filed on Mar. 12, 2020.

(51) Int. Cl. H01J 37/20; H01J 37/28; H01J 37/147

(52) U.S. Cl. CPC H01J 37/20; H01J 37/28; H01J 37/1472; H01J 2237/24578; H01J 2237/20278

(57) ABSTRACT

Apparatuses, systems, and methods for generating a beam for inspecting a wafer positioned on a stage in a charged particle beam system are disclosed. In some embodiments, a controller may include circuitry configured to classify a plurality of regions along a stripe of the wafer by type of region, the stripe being larger than a field of view of the beam, wherein the classification of the plurality of regions includes a first type of region and a second type of region; and scan the wafer by controlling a speed of the stage based on the type of region, wherein the first type of region is scanned at a first speed and the second type of region is scanned at a second speed.

### CROSS-REFERENCE TO RELATED APPLICATIONS

This application claims priority of U.S. application 62/988,817 which was filed on Mar. 12, 2020, and which is incorporated herein in its entirety by reference.

### FIELD

The description herein relates to the field of charged particle beam systems, and more particularly to high throughput charged particle beam inspection systems.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for generating a beam for inspecting a wafer positioned on a stage in a charged particle beam system. In some embodiments, a controller may include circuitry configured to classify a plurality of regions along a stripe of the wafer by type of region, the stripe being larger than a field of view of the beam, wherein the classification of the plurality of regions include a first type of region and a second type of region; and scan the wafer by controlling a speed of the stage based on the type of region, wherein the first type of region is scanned at a first speed and the second type of region is scanned at a second speed.

In some embodiments, a method may include classifying a plurality of regions along a stripe of the wafer by type of region, the stripe being larger than a field of view of the beam, wherein the classification of the plurality of regions includes a first type of region and a second type of region; and scanning the wafer by controlling a speed of the stage based on the type of region, wherein the first type of region is scanned at a first speed and the second type of region is scanned at a second speed.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary multi-beam system that is part of the exemplary charged particle beam inspection system of FIG. 1, consistent with embodiments of the present disclosure.

FIG. 3 is an illustration of a scanning sequence of a charged particle beam, consistent with embodiments of the present disclosure.

FIG. 4 is a schematic diagram of an inspection of a sample using a charged particle beam, consistent with embodiments of the present disclosure.

FIG. 5 is a schematic diagram of an inspection of a sample using a charged particle beam, consistent with embodiments of the present disclosure.

FIGS. 6A-6D are schematic diagrams of an inspection of a sample using a charged particle beam and the associated beam movement pattern during inspection, consistent with embodiments of the present disclosure.

FIG. 7 is exemplary inspection data for a charged particle beam inspection, consistent with embodiments of the present disclosure.

FIG. 8 is a flowchart illustrating an exemplary method of generating a beam for inspecting a wafer, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed in the proper location. If the structure is defective, then the process can be adjusted so the defect is less likely to recur.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

However, wafers may include areas that need to be inspected and areas that do not need to be inspected. When a wafer includes both of these areas, the inspection time may be wasted scanning the areas that do not need to be inspected, thereby reducing overall wafer throughput (which indicates how fast an imaging system can complete an inspection task in unit time). Moreover, for areas that need to be inspected, some areas may have less features to scan than others.

Conventional systems suffer from inefficient scanning in that they do not consider that some areas on the wafer may do not need to be inspected or that some areas on the wafer have less features than other areas. Accordingly, these conventional systems provide throughput that is less than optimal.

Some embodiments of the present disclosure provide improved scanning techniques that take into consideration areas on the wafer that do not need to be inspected or that some areas on the wafer have less features than other area. This disclosure describes, among others, methods and systems for generating a beam for inspecting a wafer positioned on a stage. In some embodiments, the inspection system may include a controller including circuitry to control movement of the stage during inspection. The stage may be moved continuously during inspection. The speed of the stage may be adjusted to speed up when the imaging system is scanning an area of the wafer that does not need to be inspected. Moreover, the speed of the stage can be adjusted based on the features in an area to be inspected. For example, areas that are more heavily populated with features may require a slower stage speed to increase the quality and accuracy of the inspection, while areas that are less heavily populated with features may allow for the system to increase the stage speed.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

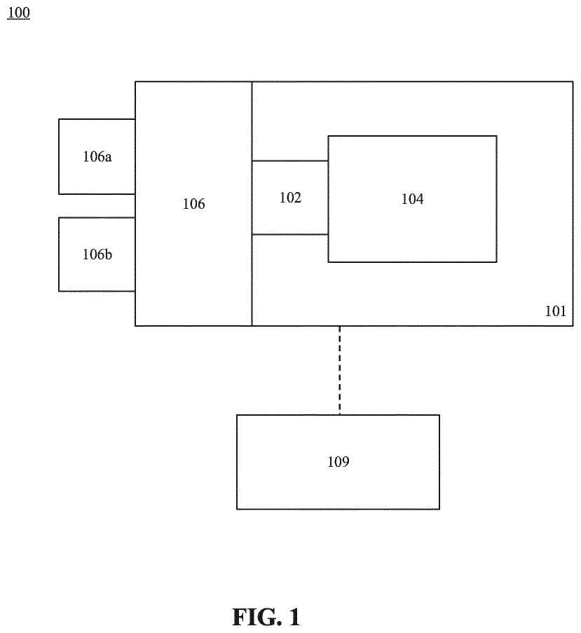

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

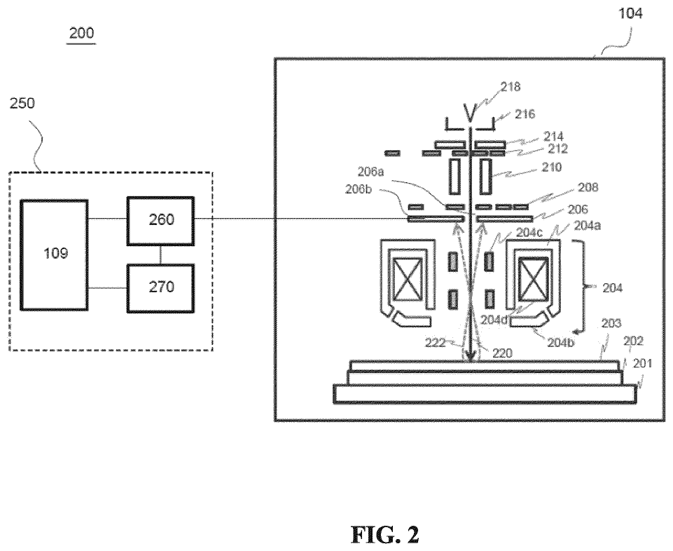

Reference is now made to FIG. 2, which is a schematic diagram illustrating an exemplary electron beam tool 104 that is part of the EBI system 100 of FIG. 1, consistent with embodiments of the present disclosure. Electron beam tool 104 may be a single beam apparatus or a multi-beam apparatus.

As shown in FIG. 2, electron beam tool 104 may include a motorized sample stage 201, and a wafer holder 202 supported by motorized stage 201 to hold wafer 203 to be inspected. Electron beam tool 104 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an energy dispersive X-ray spectrometer (EDS) detector (not shown) to characterize the materials on wafer 203.

A primary charged-particle beam 220, for example, an electron beam may be emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary charged-particle beam 220 before the beam enters objective aperture 208 to set the size of the primary electron beam before entering objective lens assembly 204. Deflector 204c deflects primary electron beam 220 to facilitate beam scanning on wafer 203. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 104 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or external structures of wafer 203.

Imaging system 200 may be used for inspecting a wafer 203 on stage 201, and comprises an electron beam tool 104, as discussed above. Imaging system 200 may also comprise an image processing system 250 that includes an image acquirer 260, a storage 270, and controller 109. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with a detector 206 of electron beam tool 104 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

Although FIG. 2 shows that apparatus 104 uses one electron beam, it is appreciated that apparatus 104 may use two or more number of primary electron beams. The present disclosure does not limit the number of primary electron beams used in apparatus 104.

Embodiments of this disclosure provide a system with the capability of optimizing throughput for different scan modes by using a single charged-particle beam imaging system (“single-beam system”) or a multiple charged-particle beam imaging system (“multi-beam system”), adapting to different throughputs and resolution requirements.

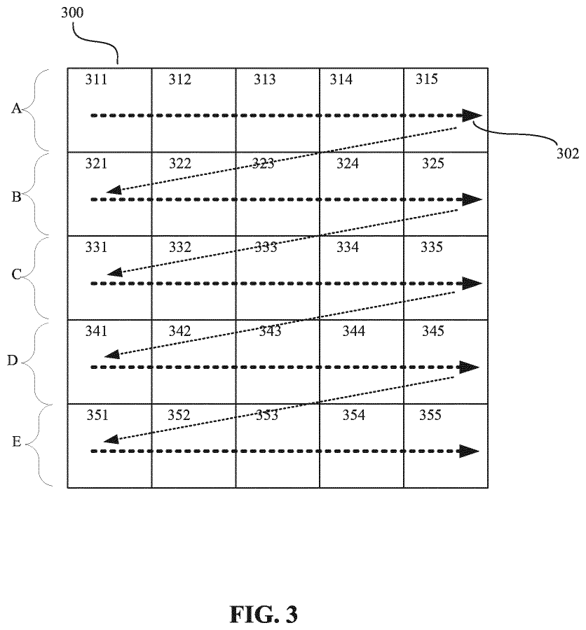

Reference is now made to FIG. 3, an illustration of a scanning sequence of a charged particle beam. An electron beam tool (e.g., electron beam tool 104 of FIG. 2) may generate images by continuous raster scanning an electron beam 302 over a wafer sample 300. The speed of a motorized stage (e.g., motorized stage 209 of FIG. 2) may be controlled so that the speed of the stage holding the wafer sample may vary during inspection and so that the wafer may be continuously scanned. FIG. 3 shows an exemplary sequence of continuous raster scanning to generate a five-by-five-pixel image. In raster scanning, the electron beam moves horizontally at one or more rates from left to right (e.g., from pixel 311 to pixel 315) to scan stripe (or line) A of pixels (e.g., pixels 311, 312, 313, 314, and 315) across wafer 300. In some embodiments, electron beam 302 may have a size (e.g., diameter) that is large enough to scan an entire pixel (e.g., pixel 311). Once electron beam 302 reaches the last pixel (e.g., pixel 315) of the stripe being scanned (e.g., stripe A), the beam rapidly moves back to the first pixel of the next stripe (e.g., pixel 321 of stripe B), where scanning of the next row may start. These steps may be repeated for pixels 321-325 of stripe B, pixels 331-335 of stripe C, pixels 341-345 of stripe D, and pixels 351-355 of stripe E. In back and forth scanning, rather than always scanning in one direction, some stripes may be scanned in one direction while other stripes may be scanned in a second opposite direction. For example, after scanning pixels 311-315, the electron beam can be adjusted vertically to align with stripe B, and the beam may then scan 325-321. The electron beam may scan some stripes in a first direction (e.g., stripes A, C, and E scanned from left to right), and may scan other stripes in a second direction opposite of the first direction (e.g., stripes C and D scanned from right to left). In some embodiments, electron beam 302 may be repositioned to a different location, where scanning of a different area of the wafer may begin. In some other embodiments, multiple beams may be used to scan the wafer using a multi-beam tool. The present disclosure does not limit the number of rows or pixels on a wafer. More information on continuous scanning using a multi-beam apparatus can be found in U.S. Patent Application No. 62/850,461, which is incorporated by reference in its entirety.

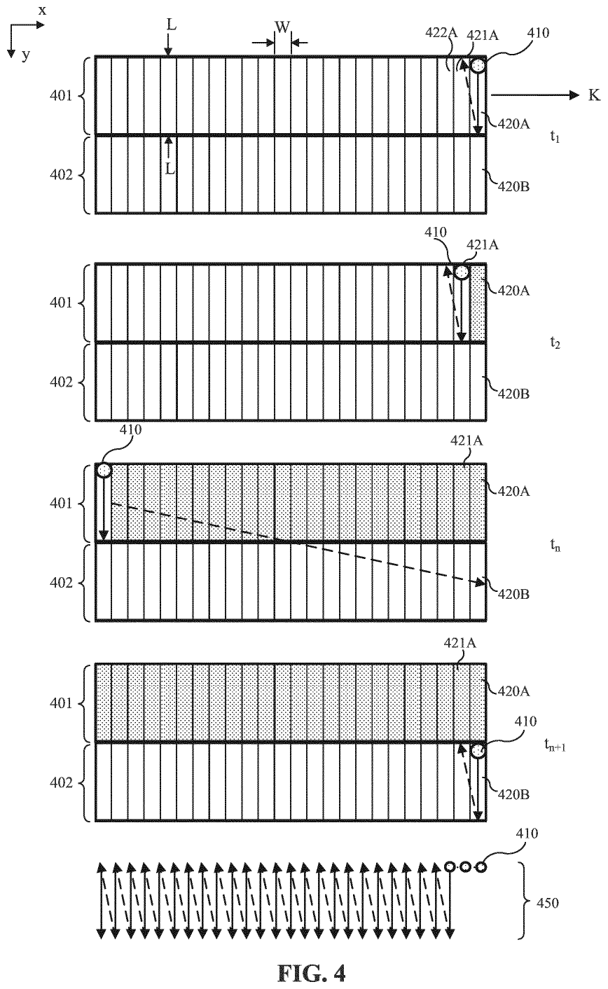

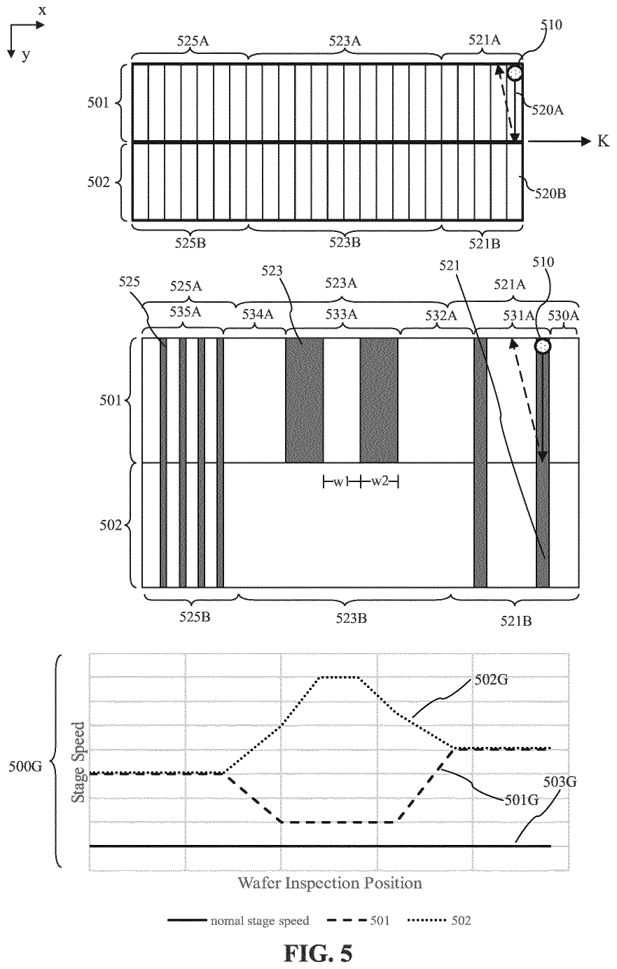

Reference is now made to FIG. 4, which schematically illustrates inspecting a sample using a charged particle beam. While FIG. 4 illustrates some scanning techniques for a raster scan, it is appreciated that similar scanning techniques can be utilized for a back and forth scan. In the embodiment illustrated by FIG. 4, a primary beamlet generates a probe spot 410 on a sample (e.g., sample 208 of FIG. 2). FIG. 4 shows the movement of probe spot 410 relative to the sample. In the illustrated embodiment, the diameter of probe spot 410 is W. However, in the disclosed embodiments, the diameter of the probe spot is not necessarily the same. In some embodiments, probe spot 410 may have a size (e.g., diameter W) that is large enough to scan an entire inspection line (e.g., inspection line 420A). Stripes 401 and 402 (e.g., stripes A, B, C, D, or E of FIG. 3; stripes 501 or 502 of FIG. 5) to be inspected are rectangular in shape but not necessarily so. Stripe 401 may include a plurality of regions (e.g., regions 521A, 523A, 525A, 521B, 523B, or 525B of FIG. 5) including a plurality of inspection lines (e.g., inspection line 420A and inspection line 421A) and stripe 402 may include a plurality of regions including a plurality of inspection lines (e.g., inspection line 420B) to be scanned. In some embodiments, one or more regions may include inspection lines with features (e.g., features 521, 523, or 525 of FIG. 5) while other regions may include inspection lines without features (e.g., regions 530A, 532A, 534A, or 523B of FIG. 5). The speed K of the motorized stage (e.g., motorized stage 209 of FIG. 2) holding the sample may be controlled to increase in regions without features to increase throughput of the inspection system. It is appreciated that a region can include one or more inspection lines. For the convenience of explanation, two directions x and y are defined in the absolute reference frame. The x and y directions are mutually perpendicular.

In some embodiments, the movements of probe spot 410 may be coordinated with the movement of the sample. For example, probe spot 410, relative to the sample, may move by length L in the y direction without moving in the y direction during time period t1, as shown in FIG. 4. In some embodiments, the speed of probe spot 410 may be controlled by adjusting the speed of the motorized stage so that the speed K of the motorized stage in a first inspection region (e.g., region 521A of FIG. 5) may be different from the speed of the motorized stage in a second inspection (e.g., region 523A of FIG. 5). The speed of the motorized stage for a plurality of inspection regions may depend on the characteristics of the inspection regions. For example, the speed of the motorized stage may depend, among others, on the presence of features, the width of the features, the periodic nature of the features, or the spacing of the features (e.g., distance between each feature) in one or more regions.

In a multi-beam system, the moving directions of a plurality of probe spots during a time period may be different. The length by which the probe spots move during time period may be different. The probe spots may or may not have movement relative to one another.

In the embodiment illustrated by FIG. 4, during time period t1, inspection line 420A may be inspected by probe spot 410. At the end of time period t1, probe spot 410 may traverse from the end of inspection line 420A to a starting point of inspection line 421A. In some embodiments, the motorized stage may be controlled to skip an inspection line without features and move so that probe spot 410 moves from the end of a first inspection line to a starting point of the next inspection line. For example, if inspection line 421A does not include one or more features and inspection line 422A does include one or more features, then probe spot 410 may traverse from the end of inspection line 420A to a starting point of inspection line 422A.

From time period t2 to tn, probe spot 410 and the sample may move in the same fashion as during time period t1. This way, stripe 401 is inspected from t1 to tn. In some embodiments, the speed of a motorized stage may be controlled so that the speed of the stage holding the wafer sample may vary during inspection and so that the wafer may be continuously scanned. Further, during the continuous scan, the beam may skip over some regions and not scan those regions.

At tn, probe spot 410 may traverse from the end of the last inspection line of stripe 401 to a starting point of inspection line 420B of stripe 402. Starting at tn+1, probe spot 410 and the sample may move in the same fashion as described above for stripe 401. In some embodiments, the speed of a motorized stage may be controlled so that the speed of the stage holding the wafer sample may vary during inspection of stripe 402 and so that the wafer may be continuously scanned. Probe spot 410 and the sample may continue to move in the same fashion as described above for stripes 401 and 402 for the entire wafer during inspection. While FIG. 4 illustrates a technique where stripe 401 is first scanned right to left, and then a diagonal jump is made to the right end of stripe 402 and it is scanned in the same right to left direction, it is appreciated that after stripe 401 is scanned, stripe 402 can be scanned from left to right with the beam transitioning from the left inspection line of stripe 401 to the left inspection line of stripe 402. It is further appreciated that this type of alternating back and forth scan can be used to inspect the stripes of a sample.

A deflector (e.g., deflector 204C of FIG. 2) that may be communicatively coupled to the controller (e.g., controller 109 of FIGS. 1-2) which may be configured to deflect the beam during inspection such that a pattern 450 of the beam interacting with the deflector and the sample may be a raster pattern during inspection while the inspection speed varies. For example, the deflector may deflect the beam in a direction that is diagonal to the direction y, direction y being perpendicular to direction x and direction x being the direction in which the motorized stage moves during a continuous scan inspection. Inspection throughput may be increased by the deflector continuously deflecting the beam in a direction diagonal to the direction y in which probe spot 410 moves along an inspection line of the sample while the speed of the motorized stage varies. In some embodiments, the deflector may swing to different positions to compensate the varying movement of the motorized stage so that the acquired images are not distorted. Although probe spot 410 is depicted as moving along an inspection line of the sample in the direction y, it is appreciated that the trajectory of the beam as it moves along each inspection line may be slightly diagonal relative to a fixed position (e.g., earth) to account for the stage moving in the direction x.

The present disclosure does not limit the embodiments to those of FIG. 4. For example, the number of probe spots, stripes, regions, inspection lines, and speed of the motorized stage are not limited. In some embodiments, the speed of the motorized stage may be controlled so that the speed of the probe spot may be adjusted for different regions or inspection lines. In some embodiments, a multi-beam system may be used for scanning

Reference is now made to FIG. 5, which schematically illustrates inspecting a sample using a charged particle beam. In the embodiment illustrated by FIG. 5, a primary beamlet generates a probe spot 510 on a sample (e.g., sample 208 of FIG. 2). In some embodiments, probe spot 510 may have a size (e.g., diameter W of FIG. 4) that is large enough to scan an entire inspection line (e.g., inspection line 420A of FIG. 4, inspection lines 520A and 520B of FIG. 5). FIG. 5 shows the movement of probe spot 510 relative to the sample. Stripes 501 and 502 (e.g., stripes 401 or 402 of FIG. 4) to be inspected are rectangular in shape but not necessarily so. Stripes 501 and 502 may include a plurality of regions 521A, 523A, 525A and 521B, 523B, 525B, respectively, to be scanned. Regions 521A, 523A, and 525A may include one or more inspection lines that may include features 521, 523, 525. Regions 521B, 523B, and 525B may include one or more inspection lines that may include features 521, 523, and 525. Some inspection lines in a region may include features while other inspection lines may not include any features (e.g., the inspection lines of region 523B). Features may be particular areas of interest (e.g., device components) on a sample to be scanned by an EBI system (e.g., EBI system 100 of FIG. 1). The speed K of a motorized stage (e.g., motorized stage 209 of FIG. 2) holding the sample may be controlled to increase in regions that will not be inspected, such as where the inspection lines do not include features (e.g., region 523B), to increase throughput of the inspection system. For the convenience of explanation, two directions x and y are defined in the absolute reference frame. The x and y directions are mutually perpendicular.

In some embodiments, the movements of probe spot 510 may be coordinated with the movement of the sample. In a multi-beam system, the moving directions of a plurality of probe spots during a time period may be different. The length by which the probe spots move during time period may be different. The probe spots may or may not have movement relative to one another.

In the embodiment illustrated by FIG. 5, stripe 501 is inspected by probe spot 510. After reaching an end of the last inspection line of region 525A in stripe 501, probe spot 510 may traverse back to the starting point of an inspection line of the next stripe 502.

In some embodiments, the speed of a motorized stage may be controlled so that the speed of the stage holding the wafer sample may vary during inspection and so that the wafer may be continuously scanned.

The present disclosure does not limit the embodiments to that of FIG. 5. For example, the number of probe spots, stripes, regions, inspection lines, and speed of the motorized stage are not limited. In some embodiments, the speed of the motorized stage may be controlled so that the speed of the probe spot may be adjusted within each region (e.g., regions 521A, 523A, 525A, 521B, 523B, 525B). For example, the speed of the motorized stage may be different for different regions depending on the inspection lines within the region and on whether the inspection lines include features. In some embodiments, a multi-beam system may be used for scanning

Stripes 501 and 502 may be larger than a FOV of the beamlet. Stripe 501 may include regions 521A, 523A, and 525A including inspection lines with features 521, 523, and 525, respectively. Stripe 502 may include regions 521B and 525B including lines with features 521 and 525.

A controller (e.g., controller 109 of FIGS. 1-2) includes circuitry configured to classify a plurality of regions along stripes 501 and 502 by types of regions. For example, region 525A may be a first type of region, region 523A may be a second type of region, and region 521A may be a third type of region. In some embodiments, regions 521A, 523A, and 525A on stripe 501 may include inspection lines without features. In some embodiments, the regions may be classified so that an inspection line with a feature may be one type of region and an inspection line without features may be another type of region. In some embodiments, a region between features 523 may have a width w1 and be classified as a first type of region. In some embodiments, feature 523 may have a width w2 and be classified as a second type of region. The present disclosure does not limit the embodiments of FIG. 5. For example, the number of inspection lines, regions, features, and stripes are not limited. In some embodiments, any of the inspection lines may be different or the same types of regions. In some embodiments, the circuitry may be configured to classify regions along stripes based on the presence of features, the width of the features, the periodic nature of the features, or the spacing of the features (e.g., distance between each feature).

In some embodiments, the speed of a motorized stage (e.g., motorized stage 209 of FIG. 2) may be controlled so that the speed of the stage holding the sample may vary during inspection based on the type of region on the sample and so that the wafer may be continuously scanned. For example, on stripe 501, the regions may be classified such that region 535A including one or more inspection lines with features 525 may be classified as a first type of region, region 534A including one or more inspection lines without features may be classified as a second type of region, region 533A including one or more inspection lines with features 523 may be classified as a third type of region, region 532A including one or more inspection lines without features may be a fourth type of region, region 531A including one or more inspection lines with features 521 may be classified as a fifth type of region, and region 530A including one or more inspection lines without features may be classified as a sixth type of region. The speed of the motorized stage may be controlled so that during inspection, the motorized stage moves at a first speed for the first type of region, a second speed for the second type of region, a third speed for the third type of region, a fourth speed for the fourth type of region, a fifth speed for the fifth type of region, and a sixth speed for the sixth type of region. The first speed may be determined based on, among others, a width between each feature 525 or a width of each feature 525. The second speed may be determined based on, among others, a width of region 534A. The third speed may be determined based on, among others, a width between each feature 523 or a width of each feature 523. The fourth speed may be determined based on, among others, a width of region 532A. The fifth speed may be determined based on, among others, a width between each feature 521 or a width of each feature 521. The sixth speed may be determined based on, among others, a width of region 530A.

In some embodiments, the speed of the motorized stage may be greater for regions or inspection lines that do not have features or areas of interest than for regions or inspection lines that do have features or areas of interest. In some embodiments, the speed of the motorized stage may be greater for longer regions that will not be inspected than for shorter regions that will not be inspected to both increase inspection throughput and to maintain greater accuracy of obtaining each generated image. Similarly, in some embodiments the speed of the motorized stage may be lower for features with longer widths than for features with shorter widths to both increase inspection throughput and to maintain greater accuracy. In some embodiments, the speed of the motorized stage may be greater for regions or inspection lines with longer widths between features (e.g., w1) than for regions or inspection lines with shorter widths between features.

In some embodiments, the speed of the motorized stage may be calculated based on the classifications of the regions, the pixel size, the FOV, or the system data rate (e.g., 400 MHz, 100 MHz).

In some embodiments, the motorized stage may continuously move so that probe spot 510 may continuously move along stripe 501 and traverse to stripe 502. For stripe 502, region 525B may be classified as a first type of region, region 523B may be classified as a second type of region, and region 521B may be classified as a third type of region. As described for stripe 501, the speed of the motorized stage may be controlled so that during inspection, the motorized stage moves at a first speed for the first type of region, a second speed for the second type of region, and a third speed for the third type of region. The first speed may be determined based on, among others, a width between each feature of inspection lines 525 or a width of each feature of inspection lines 525. The second speed may be determined based on, among others, a width of region 523B. The third speed may be determined based on, among others, a width between each feature of inspection lines 521 or a width of each feature of inspection lines 521. As described for stripe 501, the speed of the motorized stage may be greater for regions or inspection lines that do not have features than for regions or inspection lines that do have features. In some embodiments, the speed of the motorized stage may be greater for longer regions that will not be inspected than for shorter regions that will not be inspected to both increase inspection throughput and to maintain greater accuracy of obtaining each generated image. Similarly, in some embodiments the speed of the motorized stage may be lower for features with longer widths than for features with shorter widths to both increase inspection throughput and to maintain greater accuracy. In some embodiments, the speed of the motorized stage may be greater for regions or inspection lines with longer widths between features than for regions or inspection lines with shorter widths between features. In any embodiment, the beamlet may continuously scan any region of the sample during inspection.

For example, graph 500G depicts the speed of the stage holding the wafer as a function of the position of a probe spot on the wafer in the x direction. Curve 503G depicts the constant speed of a stage in a conventional inspection system while 501G depicts the speed of the stage during inspection of stripe 501 and curve 502G depicts the speed of the stage during inspection of stripe 502, consistent with the disclosed embodiments. The horizonal axis may be the position of probe spot 510 on the wafer in the x direction and the vertical axis may be the speed of the stage. As shown by curve 501G, the speed of the stage over stripe 501 is lower over region 533A than the speed of the stage over stripe 501 over inspection regions 531A and 535A. For example, the speed of the stage over region 531A of stripe 501 may be higher than for region 533A of stripe 501 since the proportion of region 531A containing features may be lower than the proportion of region 533A containing features, indicating a possible need for a lower stage speed when inspecting region 533A than for region 531A. Similarly, the speed of the stage over region 535A of stripe 501 may be higher than for region 533A of stripe 501 since the proportion of region 535A containing features may be lower than the proportion of region 533A containing features. The speed of the stage over region 535A of stripe 501 may be lower than for region 531A of stripe 501 since the proportion of region 535A containing features may be higher than the proportion of region 531A containing features, indicating a possible need for a lower speed stage when inspecting region 535A.

Similarly, curve 502G shows that the speed of the stage over stripe 502 increases from region 525B to region 523B and decreases for region 521B since region 523B does not include features, indicating that region 523B does not need careful inspection. Overall inspection throughput may be increased since the overall speed of the stage may increase during inspection as compared to conventional systems (see, e.g., curve 503G).

In some embodiments, regions that will not be inspected may include features (e.g., the risk level of the defects in that region may be low, indicating that the region does not need to be inspected).

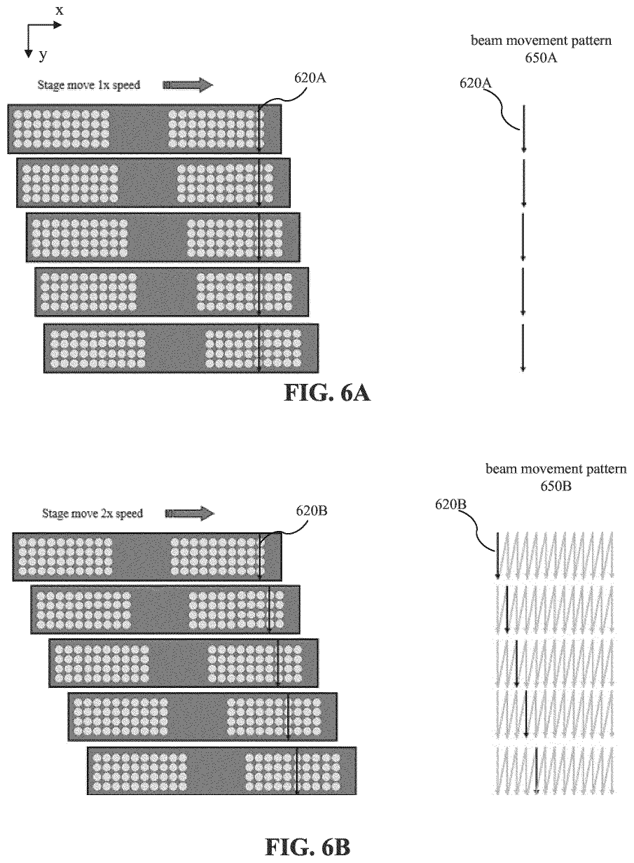

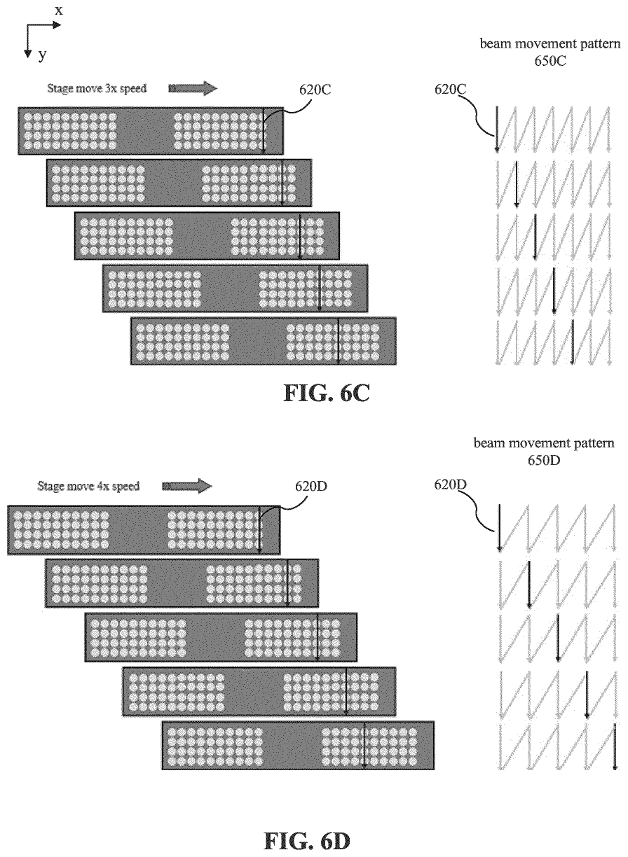

Reference is now made to FIGS. 6A-6D, which schematically illustrate inspecting a sample using a charged particle beam and the associated beam movement pattern during inspection. While FIGS. 6A-6D show the beam scanning in a y direction while scanning an inspection line (e.g. 620A-D), in a continuous scan mode, while the beam will scan in a y direction relative to the sample, it will also move in a diagonal direction relative to a fixed position (e.g., earth), where the x component of the diagonal is to compensate for the x direction movement of the sample. A deflector (e.g., deflector 204c of FIG. 2) that may be communicatively coupled to the controller (e.g., controller 109 of FIGS. 1-2) may be configured to deflect the beam during inspection such that the speed of the beam may vary along the sample during inspection while the inspection speed varies. For example, a probe spot may scan an inspection line in the direction y and the deflector may deflect the beam in a direction that is diagonal to the direction y. In some embodiments, the deflector may swing to different positions to compensate the varying movement of the motorized stage so that the acquired images are not distorted. Inspection throughput is increased by the deflector continuously deflecting the beam in a direction diagonal to the direction y in which the probe spot moves along the sample while the speed of the motorized stage varies. Although the probe spot is depicted as moving along an inspection line of the sample in the direction y, it is appreciated that the trajectory of the beam relative to a fixed position (e.g., earth) may be slightly diagonal to account for the stage moving in the direction x.

In a first example, FIG. 6A depicts a stage moving at a normal speed (e.g., 1×) and its associated beam pattern movement during inspection of a wafer. Beam pattern 650A shows that the beam pattern along each inspection line 620A may remain the same with respect to a stationary reference as the stage moves in the direction x at a normal speed. It should be appreciated that the illustration is an approximation, and that the path of the beam may be a diagonal offset in the y direction. Further, the path of the diagonal may be repeated for each inspection line scan, with the scan path for each inspection line scan remaining the same with respect to a stationary reference (e.g., earth). Similarly, FIGS. 6B, 6C, and 6D each depict the stage moving at 2×, 3×, and 4× the normal speed, respectively, and their associated beam pattern movement during inspection of a wafer. As shown by patterns 650B, 650C, and 650D of FIGS. 6B-6D, respectively, the deflector may be configured to deflect the beam during inspection such that the speed of the beam that scans each inspection line 620B-D (e.g., inspection line 420A of FIG. 4, inspection line 520A of FIG. 5) in the direction y or the direction may increase as the speed of the stage moving in the direction x increases. Further, the position of the beam on the wafer along the direction x may vary depending on the regions on the wafer to be inspected. For example, when the speed of the stage is 4× the normal speed, as shown in FIG. 6D, beam pattern 650D shows that the beam may travel twice the direction x width between each inspection line 620D than when the speed of the stage is 2× the normal speed (see, e.g., FIG. 6B).

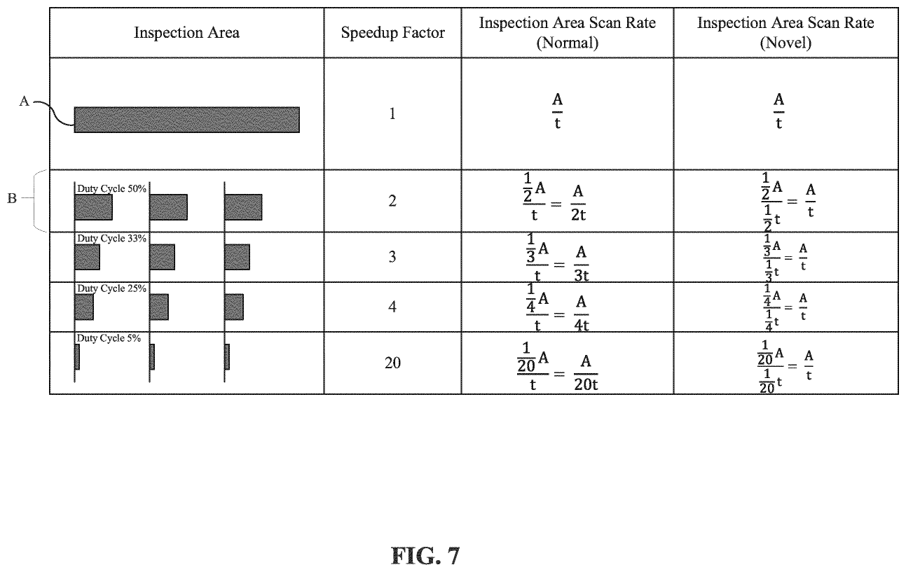

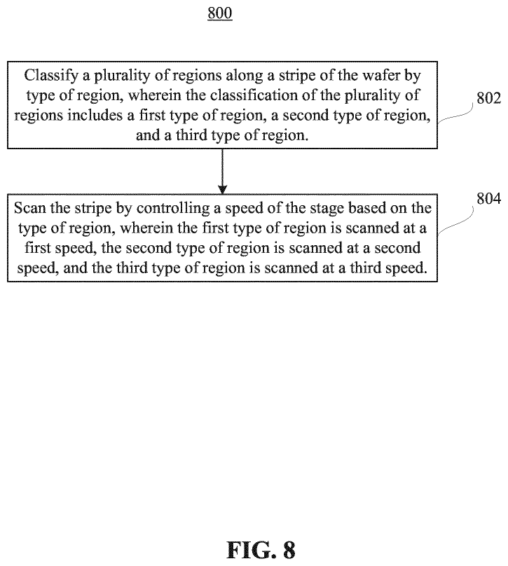

Reference is now made to FIG. 7, which shows exemplary inspection data for a charged particle beam inspection. An inspection area A with a feature may have a normal speedup factor 1 (e.g., the normal stage speed), where the inspection area rate is calculated by the area of inspection region A divided by inspection time t. For inspection region A, the throughput gain would be zero since the speedup factor is 1 (e.g., the normal stage speed). An inspection region B may have a duty cycle of 50%. For example, half of the scan lines of inspection region B may include features to be inspected while half of the scan lines of inspection region B may not need to be inspected, meaning the area to be inspected of region B may be one-half the area to be inspected of region A. The speedup factor of inspection region B may be 2 (e.g., 2× the normal stage speed) since one-half of region B will not be inspected. In some embodiments, the inspection rate of inspection region B would be one-half the inspection rate of inspection area A since only one-half of inspection region B would be scanned at the normal stage speed for the same amount of time t. The speedup factor of 2 may increase the inspection rate of inspection region B to A/t, since one-half of region B is scanned in one-half of the normal time t. In this example, the throughput gain would increase by a factor of 2 since the stage speed while inspecting region B would be twice the stage speed while inspecting region A since only half of region B may be inspected as compared to region A. The present disclosure does not limit the embodiments of FIG. 7. For example, the number, width, and shape of the care areas are not limited. Similarly, the speedup factors are not limited.

FIG. 8 is a flowchart illustrating an exemplary method 800 of generating a beam for inspecting a wafer positioned on a stage. Method 800 may be performed by an EBI system (e.g., EBI system 100). A controller (e.g., controller 109 of FIGS. 1-2) may be programmed to implement method 800. For example, the controller may be an internal controller or an external controller coupled with the electron beam tool (e.g., electron beam tool 104 of FIG. 2). Method 800 may be connected to the operations and steps as shown and described in FIGS. 3-7.

At step 802, the EBI system may classify a plurality of regions along a stripe of the wafer by types of regions, the stripe being larger than a field of view of the beam, wherein the classification of the plurality of regions includes a first type of region with features that are to be inspected (e.g., region 525B of FIG. 5), a second type of region that does not need to be inspected (e.g., region 523B of FIG. 5), and a third type of region with features that are to be inspected (e.g., region 521B of FIG. 5). For example, a controller of the EBI system may include circuitry configured to classify a plurality of regions along stripes (e.g., stripes 501 and 502 of FIG. 5) by types of regions. The EBI system may determine that the first type of region includes a plurality of first inspection lines with features (e.g., features 525 of FIG. 5), the second type of region includes one or more second inspection lines that do not need to be inspected (e.g., region 523B of FIG. 5), and the third type of region includes a plurality of third inspection lines with features (e.g., features 521 of FIG. 5). These determinations may be based on the presence of features in those regions, the width of the features, the periodic nature of the features, the spacing of the features (e.g., distance between each feature), the risk level of defects in a region, or a combination thereof. For example, the EBI system may determine that an inspection region (e.g., inspection region B of FIG. 7) that is one-half the area of a normal inspection area (e.g., inspection area A of FIG. 7) may be a first type of inspection region.

At step 804, the EBI system may scan the stripe by controlling a speed of the stage based on the type of region, wherein the first type of region is scanned at a first speed, the second type of region is scanned at a second speed, and the third type of region is scanned a third speed. For example, a first speed for the first type of region may be determined based on a width between each feature of each first inspection line of the plurality of first inspection lines and based on a width of each feature of each first inspection line of the plurality of first inspection lines, a second speed may be determined based on a width of the second type of region and the absence of features in the second region, and a third speed may be determined based on a width between each feature of each third inspection line of the plurality of third inspection lines and based on a width of each feature of each third inspection line of the plurality of third inspection lines. The controller may include circuitry configured to control a speed of the stage (e.g., motorized stage 209 of FIG. 2) based on the type of region on the sample (e.g., wafer sample 208 of FIG. 2). In some embodiments, the speed of the motorized stage may be greater for regions without features with longer widths than for regions without features with shorter widths to both increase inspection throughput and to maintain greater accuracy of obtaining each generated image Similarly, the speed of the motorized stage may be greater for regions with shorter features than for regions with longer features to both increase inspection throughput and to maintain greater accuracy. The speed of the motorized stage may be greater for regions with longer widths between each feature than for regions with shorter widths between each feature. For example, the second speed may be greater than the first speed and the third speed. For example, a first type of inspection region (e.g., inspection region B of FIG. 7) may have a speedup factor of 2 (e.g., 2× the normal stage speed) if the first type of inspection region is one-half the area of a normal inspection area (e.g., inspection area A of FIG. 7).

Aspects of the present disclosure are set out in the following numbered clauses:
1. A charged particle beam system for generating a beam for inspecting a wafer positioned on a stage, the system comprising:
   a controller including circuitry configured to:
      classify a plurality of regions along a stripe of the wafer by type of region, the stripe being larger than a field of view of the beam, wherein the classification of the plurality of regions includes a first type of region and a second type of region; and
      scan the wafer by controlling a speed of the stage based on the type of region, wherein the first type of region is scanned at a first speed and the second type of region is scanned at a second speed.
2. The system of clause 1, further comprising a deflector that is communicatively coupled to the controller and configured to produce detection data based on a detection of a charged particle associated with the beam interacting with the wafer.
3. The system of clause 2, wherein the deflector is further configured to deflect the beam such that a pattern of the beam's movement remains constant during inspection.
4. The system of any one of clauses 1-3, wherein controlling the speed of the stage involves operating the stage in a continuous scan mode.
5. The system of any one of clauses 1-4, the controller including circuitry further configured to classify a plurality of regions along each of a plurality of stripes of the wafer by types of regions, each stripe being larger than a field of view of the beam.
6. The system of any one of clauses 1-5, wherein the first and second types of regions each comprise a plurality of inspection lines.
7. The system of any one of clauses 1-6, wherein the first type of region comprises a first feature.
8. The system of clause 7, wherein the first speed is determined based on a width of the first feature or a density of features in the first type of region.
9. The system of any one of clauses 7-8, wherein the first type of region comprises a plurality of first features wherein the first speed is determined based on a width between each feature of the plurality of first features.
10. The system of any one of clauses 7-9, wherein the second type of region comprises a second feature different from the first feature.
11. The system of clause 10, wherein the second speed is determined based on a width of the second feature, wherein the width of the second feature is different from the width of the first feature.
12. The system of clause 11, wherein a ratio of the first speed and the second speed is substantially similar to a ratio of the width of the second feature and the width of the first feature.
13. The system of any one of clauses 7-12, wherein the second type of region comprises a plurality of second features and wherein the second speed is determined based on a width between each feature of the plurality of second features.
14. The system of any one of clauses 7-13, wherein the classification of the plurality of regions includes a third type of region.
15. The system of clause 14, wherein the third type of region is between the first type of region and the second type of region.
16. The system of any one of clauses 14 or 15, wherein the third type of region is scanned at a third speed different from the first and second speeds.
17. The system of clause 16, wherein the third speed is determined based on a lack of features to be scanned in the third type of region.
18. The system of any one of clauses 16 or 17, wherein the third speed is greater than the first speed and the second speed.
19. The system of any one of clauses 1-5, wherein the first speed is determined based on a width of the first type of region.
20. The system of any one of clauses 1-5 or 19, wherein the second speed is determined based on a width of the second type of region.
21. The system of any one of clauses 7-18, wherein the first speed is determined based on a proportion of the first type of region that includes the first feature.
22. The system of any one of clauses 10-18 or 21, wherein the second speed is determined based on a proportion of the second type of region that includes the second feature.
23. The system of any one of clauses 14-18, 21, or 22, wherein the third speed is determined based on a proportion of the third type of region that includes a third feature.
24. A method for generating a beam for inspecting a wafer positioned on a stage, the method comprising:
   classifying a plurality of regions along a stripe of the wafer by type of region, the stripe being larger than a field of view of the beam, wherein the classification of the plurality of regions includes a first type of region and a second type of region; and
   scanning the wafer by controlling a speed of the stage based on the type of region, wherein the first type of region is scanned at a first speed and the second type of region is scanned at a second speed.
25. The method of clause 24, further comprising a deflector that is communicatively coupled to the controller and configured to produce detection data based on a detection of a charged particle associated with the beam interacting with the wafer.
26. The method of clause 25, wherein the deflector is further configured to deflect the beam such that a pattern of the beam's movement remains constant during inspection.
27. The method of any one of clauses 24-26, wherein controlling the speed of the stage involves operating the stage in a continuous scan mode.
28. The method of any one of clauses 24-27, further comprising classifying a plurality of regions along each of a plurality of stripes of the wafer by types of regions, each stripe being larger than a field of view of the beam.
29. The method of any one of clauses 24-28, wherein the first and second types of regions each comprise a plurality of inspection lines.
30. The method of any one of clauses 24-29, wherein the first type of region comprises a first feature.
31. The method of clause 30, wherein the first speed is determined based on a width of the first feature or a density of features in the first type of region.
32. The method of any one of clauses 30-31, wherein the first type of region comprises a plurality of first features wherein the first speed is determined based on a width between each feature of the plurality of first features.
33. The method of any one of clauses 30-32, wherein the second type of region comprises a second feature different from the first feature.
34. The method of clause 33, wherein the second speed is determined based on a width of the second feature, wherein the width of the second feature is different from the width of the first feature.
35. The system of clause 34, wherein a ratio of the first speed and the second speed is substantially similar to a ratio of the width of the second feature and the width of the first feature.
36. The method of any one of clauses 30-35, wherein the second type of region comprises a plurality of second features and wherein the second speed is determined based on a width between each feature of the plurality of second features.
37. The method of any one of clauses 30-36, wherein the classification of the plurality of regions includes a third type of region.
38. The method of clause 37, wherein the third type of region is between the first type of region and the second type of region.
39. The method of any one of clauses 37-38, wherein the third type of region is scanned at a third speed different from the first and second speeds.
40. The method of clause 39, wherein the third speed is determined based on a lack of features to be scanned in the third type of region.
41. The method of any one of clauses 39-40, wherein the third speed is greater than the first speed and the second speed.
42. The method of any one of clauses 24-28, wherein the first speed is determined based on a width of the first type of region.
43. The method of any one of clauses 24-28 or 42, wherein the second speed is determined based on a width of the second type of region.
44. The method of any one of clauses 30-41, wherein the first speed is determined based on a proportion of the first type of region that includes the first feature.
45. The method of any one of clauses 33-41 or 44, wherein the second speed is determined based on a proportion of the second type of region that includes the second feature.
46. The method of any one of clauses 37-41, 44, or 45, wherein the third speed is determined based on a proportion of the third type of region that includes a third feature.

A non-transitory computer readable medium may be provided that stores instructions for a processor (e.g., processor of controller 109 of FIGS. 1-2) to carry out image processing, data processing, beamlet scanning, database management, graphical display, operations of a charged particle beam apparatus, or another imaging device, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof.

1. A charged particle beam system for generating a beam for inspecting a wafer positioned on a stage, the system comprising:
a controller including circuitry configured to:
classify a plurality of regions along a stripe of the wafer by type of region, the stripe being larger than a field of view of the beam, wherein the classification of the plurality of regions includes a first type of region and a second type of region; and
scan the wafer by controlling a speed of the stage based on the type of region, wherein the first type of region is scanned at a first speed and the second type of region is scanned at a second speed.

2. The system of claim 1, further comprising a deflector that is communicatively coupled to the controller and configured to produce detection data based on a detection of a charged particle associated with the beam interacting with the wafer.

3. The system of claim 2, wherein the deflector is further configured to deflect the beam such that a pattern of the beam's movement remains constant during inspection.

4. The system of claim 1, wherein controlling the speed of the stage involves operating the stage in a continuous scan mode.

5. The system of claim 1, the controller including circuitry further configured to classify a plurality of regions along each of a plurality of stripes of the wafer by types of regions, each stripe being larger than a field of view of the beam.

6. The system of claim 1, wherein the first and second types of regions each comprise a plurality of inspection lines.

7. The system of claim 1, wherein the first type of region comprises a first feature.

8. The system of claim 7, wherein the first speed is determined based on a width of the first feature or a density of features in the first type of region.

9. The system of claim 7, wherein the first type of region comprises a plurality of first features wherein the first speed is determined based on a width between each feature of the plurality of first features.

10. The system of claim 7, wherein the second type of region comprises a second feature different from the first feature.

11. The system of claim 10, wherein the second speed is determined based on a width of the second feature, wherein the width of the second feature is different from the width of the first feature.

12. The system of claim 11, wherein a ratio of the first speed and the second speed is substantially similar to a ratio of the width of the second feature and the width of the first feature.

13. The system of claim 7, wherein the second type of region comprises a plurality of second features and wherein the second speed is determined based on a width between each feature of the plurality of second features.

14. The system of claim 7, wherein the classification of the plurality of regions includes a third type of region.

15. A method for generating a beam for inspecting a wafer positioned on a stage, the method comprising:
classifying a plurality of regions along a stripe of the wafer by type of region, the stripe being larger than a field of view of the beam, wherein the classification of the plurality of regions includes a first type of region and a second type of region; and
scanning the wafer by controlling a speed of the stage based on the type of region, wherein the first type of region is scanned at a first speed and the second type of region is scanned at a second speed.
